(19) United States
(12) Patent Application Publication
(10) Pub. No.: US 2025/0232801 A1
(43) Pub. Date: Jul. 17, 2025

(54) MEMORY CONTROL DEVICE

(71) Applicant: SONY SEMICONDUCTOR SOLUTIONS CORPORATION, KANAGAWA (JP)

(72) Inventors: TAKEHARU IKEZOE, KANAGAWA (JP); TAKAHIRO IKARASHI, KANAGAWA (JP)

(21) Appl. No.: 18/849,180

(22) PCT Filed: Mar. 9, 2023
(86) PCT No.: PCT/JP2023/009080

§ 371 Date: Sep. 20, 2024

(30) Foreign Application Priority Data
Mar. 31, 2022 (JP) 2022-059698

(51) Int. Cl. G11C 11/4096; G11C 11/4076; G11C 11/4093

(52) U.S. Cl. CPC G11C 11/4096; G11C 11/4076; G11C 11/4093

(57) ABSTRACT

A memory control device according to one embodiment of the present disclosure includes a detector and a converter. The detector detects switching between read bank group interleaving and a write request or switching between write bank group interleaving and a read request in a plurality of memory access requests received for memory access. The converter converts a BL length of a memory access request included in the read bank group interleaving or the write bank group interleaving, on the basis of a number of memory access requests in the read bank group interleaving or the write bank group interleaving and timing information of a command corresponding to a memory access request immediately before the read bank group interleaving or the write bank group interleaving.

### TECHNICAL FIELD

The present disclosure relates to a memory control device.

### BACKGROUND ART

There have been proposed various measures to access a DRAM (Dynamic Random Access Memory) more efficiently (for example, see PTL 1 and PTL 2).

### CITATION LIST

### Patent Literature

PTL 1: Japanese Unexamined Patent Application Publication No. 2021-157295
PTL2: Japanese Unexamined Patent Application Publication No. 2006-252173

### SUMMARY OF THE INVENTION

Incidentally, in existing DRAM technologies, the larger a BL (Burst Length) length is, the more efficient access to a DRAM is. However, in DRAM standards having a BG (Bank Group) and being compatible with a plurality of BL lengths, such as LPDDR (Low Power Double Date Rate) or LPDDR5X, the access to the DRAM is sometimes more efficient even in a case where the BL length is short. It is thus desirable to provide a memory control device that makes it possible to access the DRAM more efficiently in the DRAM standards having the BG and being compatible with the plurality of BL lengths.

A memory control device according to one embodiment of the present disclosure includes a detector and a converter. The detector detects switching between read bank group interleaving and a write request or switching between write bank group interleaving and a read request in a plurality of memory access requests received for memory access. The converter converts a BL length of a memory access request included in the read bank group interleaving or the write bank group interleaving, on the basis of a number of memory access requests in the read bank group interleaving or the write bank group interleaving and timing information of a command corresponding to a memory access request immediately before the read bank group interleaving or the write bank group interleaving.

In the memory control device according to one embodiment of the present disclosure, the BL length of the memory access request included in the read bank group interleaving or the write bank group interleaving is converted, on the basis of the number of memory access requests in the read bank group interleaving or the write bank group interleaving and the timing information of the command corresponding to the memory access request immediately before the read bank group interleaving or the write bank group interleaving. This makes it possible to select the BL length in consideration of the efficiency of the access to the DRAM.

### BRIEF DESCRIPTION OF DRAWING

FIG. 1 is a diagram illustrating an example of an operation of a command scheduler.

FIG. 2 is a diagram illustrating an example of an operation following FIG. 1.

FIG. 3 is a diagram illustrating an example of an operation of the command scheduler.

FIG. 4 is a diagram illustrating an example of an operation of the command scheduler.

FIG. 5 is a diagram illustrating a schematic configuration example of an information processing system including a memory control device according to one embodiment of the present disclosure.

FIG. 6 is a diagram illustrating a FIFL memory concept.

FIG. 7 is a diagram illustrating an example of data stored in a FIFO memory.

FIG. 8 is a diagram illustrating an example of an operation of a RW switching detector.

FIG. 9 is a diagram illustrating conditions for determining whether or not to convert a BL length of a command included in 2BG interleaving.

FIG. 10 is a diagram describing the conditions of FIG. 9.

FIG. 11 is a diagram describing the conditions of FIG. 9.

FIG. 12 is a diagram describing the conditions of FIG. 9.

FIG. 13 is a diagram illustrating an example of an operation of a BL conversion judging unit.

FIG. 14 is a diagram illustrating an example of an operation of the BL conversion judging unit.

FIG. 15 is a diagram illustrating an example of an operation of the BL conversion judging unit.

FIG. 16 is a diagram illustrating an example of an operation of a BL converter.

FIG. 17 is a diagram illustrating an example of data stored in the FIFO memory.

FIG. 18 is a diagram illustrating an example of a sequence of memory access requests after conversion is performed by the BL converter.

FIG. 19 is a diagram illustrating an example of data stored in the FIFO memory.

FIG. 20 is a diagram illustrating an example of the sequence of memory access requests after the conversion is performed by the BL converter.

FIG. 21 is a diagram illustrating an example of an execution procedure of out-of-order.

FIG. 22 is a diagram illustrating an example the execution procedure of the out-of-order.

FIG. 23 is a diagram illustrating an operation of the command scheduler when a sequence of an access request changing from a read request to a write request is inputted.

FIG. 24 is a diagram illustrating an operation of the command scheduler when a sequence of an access request changing from a write request to a read request is inputted.

FIG. 25 is a diagram illustrating a modification example of a schematic configuration of the information processing system of FIG. 5.

FIG. 26 is a diagram illustrating a modification example of a schematic configuration of the information processing system of FIG. 5.

FIG. 27 is a diagram illustrating the conditions for determining whether or not to convert the BL length of the command included in the 2BG interleaving.

FIG. 28 is a diagram describing the conditions of FIG. 27.

FIG. 29 is a diagram illustrating an example of data stored in the FIFO memory.

FIG. 30 is a diagram illustrating an example of the sequence of access requests after the conversion is performed by the BL converter.

### MODES FOR CARRYING OUT THE INVENTION

In the following, some embodiments of the present disclosure will be described in detail with reference to the drawings. It is to be noted, however, that the embodiments described below are merely exemplary, and there is no intention to exclude application of various modifications or technologies not explicitly described below. It is possible to implement the present technology by making various modifications (such as by combining the embodiments, for example), without departing from the spirit of the present technology. In addition, in the following description of the drawings, identical or similar portions are denoted by identical or similar reference numerals. The drawings are schematic and do not necessarily correspond to actual dimensions or proportions. In some cases, the drawings may include portions that are different in their mutual dimensional relationships or proportions.

### 1. REGARDING CHALLENGES IN THE NEWEST GENERATION STANDARDS

As a memory system, a synchronous DRAM (SDRAM: Synchronous Dynamic Random Access Memory) has been widely used that is advantageous in terms of a price, a bus band, and capacity. The SDRAM is a DRAM that operates synchronously with a clock signal and often includes a plurality of banks.

In the SDRAM with such a configuration, in a case where a same bank is continuously accessed, efficiency of access to the SDRAM is significantly reduced. In contrast, as a technique to improve the efficiency of the access to the DRAM, there has been proposed a technique to hold a plurality of access requests to the DRAM and output an access request to a bank that is different from a bank accessed last time, from among the plurality of held access requests.

In the existing DRAM technology, the larger a BL (Burst Length) length is, the more efficient the access to the DRAM is. One reason for this is that the larger BL length increases an amount of data to be transferred per usage time of an address command line, thus making it possible to reduce the usage time of the command address line. In the newest DRAM standards such as LPDDR5 or LPDDR5X, however, the access to the DRAM is sometimes more efficient even in a case where the BL length is short. The LPDDR5 and the LPDDR5X are the DRAM standards stipulated by JEDEC (Join Electron Device Engineering Council).

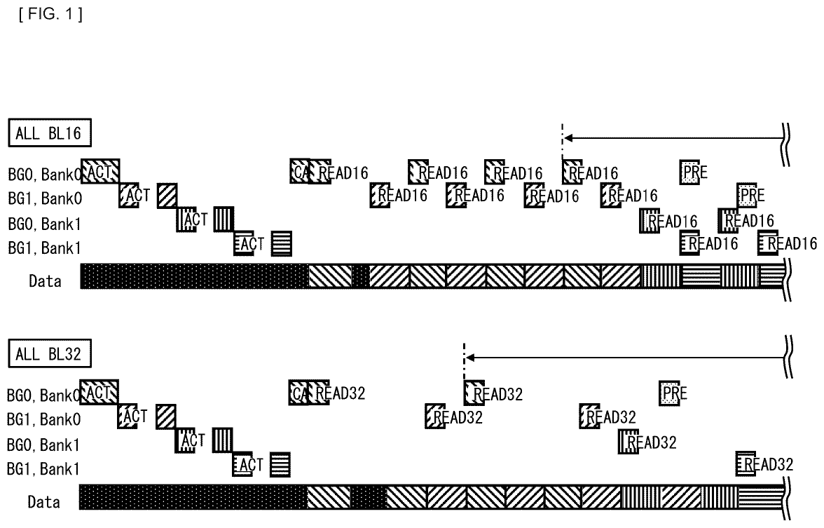

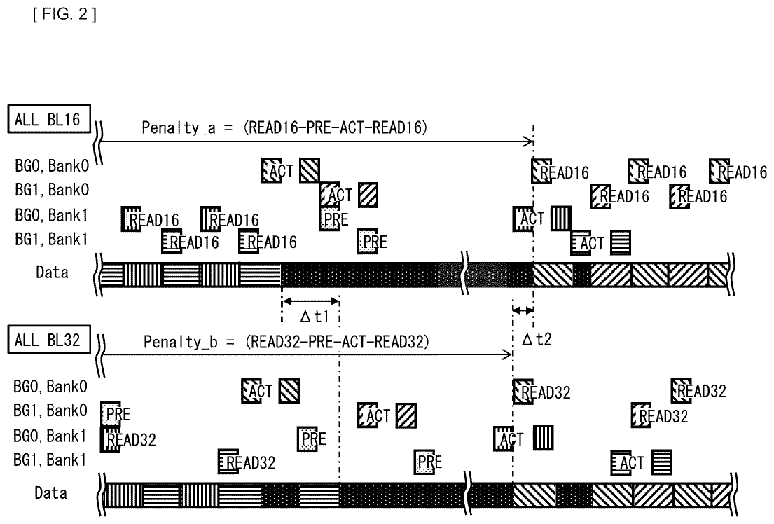

FIG. 1 and FIG. 2 each illustrate an examples of an operation of a command scheduler when two bank groups are interleaved. FIG. 2 illustrates an example of an operation following FIG. 1. Upper parts of FIG. 1 and FIG. 2 illustrate the example of the operation of the command scheduler when the BL length is BL16. Lower parts of FIG. 1 and FIG. 2 illustrate an example of an operation of the command scheduler when the BL length is BL32. In the upper and lower parts of FIG. 1 and FIG. 2, commands outputted to the address command line are illustrated, being divided for each bank group and bank address, and data outputted to a data line is represented in different patterns for each bank group and bank address. It is to be noted that portions blacked out in the data line indicate that no data is outputted.

It is to be noted that various notations in FIG. 1 and FIG. 2 refer to the following contents:
ACT: Active command
READ16: Read command with BL16
READ32: Read command with BL32
PRE: Precharge command

In addition, various parameters in FIG. 1 and FIG. 2 are specified as follows:
Command clock=800 MHz
tRRD=3nCK
tFAW=15 ns
tRCD=15nCK
tRCD_W=7nCK
nRBTP=4nCK
tRPpb=15nCK
tWR=27nCK
RL=18
   (In the figures, a delay from Read to DQ is expressed as RL=0.)
WL=9
   (In the figures, a delay from Write to DQ is expressed as WL=0.)
tRRD: Shortest interval between ACT-ACT
tFAW: Period during which up to for ACTs may be present
tRCD: Shortest interval between ACT-REAAD or ACT-MASKEDWRITE
tRCD_W: Shortest interval between ACT-WRITE
nRBTP: Shortest interval between READ-burst end-PRE
tRPpb: Shortest interval between PRE-ACT
tWR: WRTE recovery time

It is seen from FIG. 1 and FIG. 2 that in first BG interleaving, data transfer ends earlier by Δt1 with BL16 than with BL32. In second BG interleaving, however, it is seen that data transfer with BL32 starts earlier by Δt2 (=1nCK) than with BL16. One reason for this is that two or more banks have to be opened to perform BG interleaving when BL16 is used, and that the shortest interval between first two read commands is tRRD or more. Consequently, it is seen that as the BG interleaving is repeated third time, fourth time, and so on, starting time of the BG interleaving becomes earlier in increments of 1nCK with BL32 than with BL16. In addition, in fourth BG interleaving, data transfer latency reaches an equivalent level for BL16 and BL32. Therefore, it is seen that, in general, the efficiency of the access to the DRAM is more efficient with BL32 than with BL16.

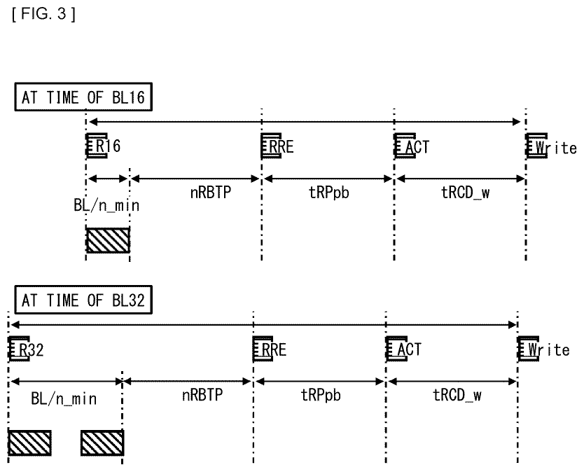

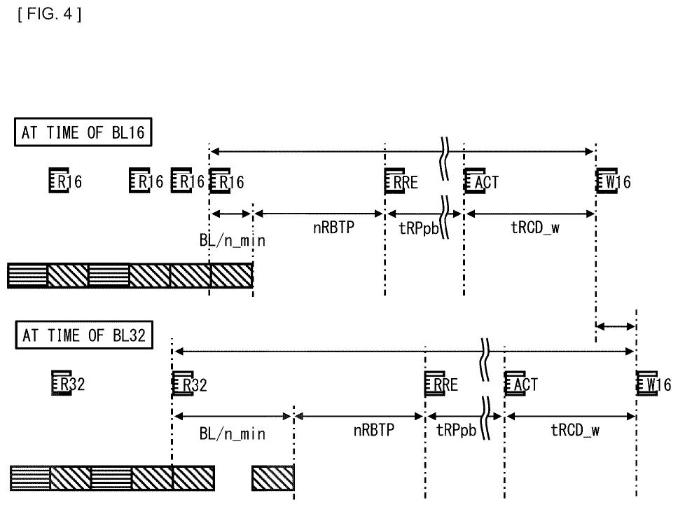

FIG. 3 and FIG. 4 each illustrate an example of an operation of the command scheduler. The upper parts of FIG. 3 and FIG. 4 illustrate an example of the command scheduler when the BL length is BL16. The lower parts of FIG. 3 and FIG. 4 illustrate an example of the command scheduler when the BL length is BL32.

It is to be noted that various notations in FIG. 3 and FIG. 4 refer to the following contents:
ACT: Active command
R16: Read command with BL16
R32: Read Command with BL32
PRE: Precharge command
Write: Write command

The data line of the DRAM is shared by reads and writes. For this reason, penalty time is necessary when switching from read to write or write to read. Here, in a BG mode, while BL/n_min of BL16 is 2, BL/n_min of BL32 is 6. Therefore, as illustrated in FIG. 3 and FIG. 4, it is seen that depending on usage conditions of the data line, a timing at which a write command is issued is earlier with BL16 than with BL32. As such, it is seen that in the newest generation standards, the efficiency of the access to the DRAM is sometimes more efficient with BL16 than with BL32.

It is seen from the above that BL32 is more efficient in accessing the DRAM than BL16 in a case there is no read/write switching, and that BL16 is more efficient in accessing the DRAM than BL32 in a case where there is read/write switching. Hence, the inventor of the present application proposes below a technique to select a BL length that improves the efficiency of the access to the DRAM during the read/write switching.

### 2. EMBODIMENT

### [Configuration]

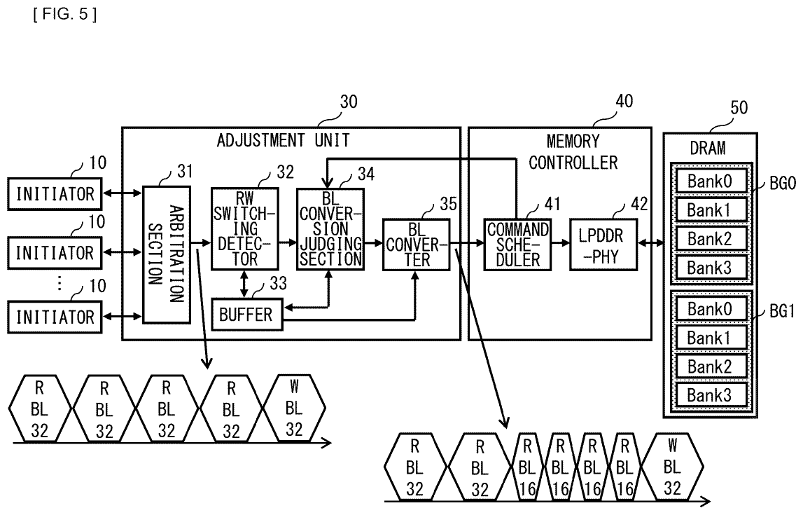

FIG. 5 illustrates an example of a schematic configuration of an information processing system including a memory control device according to one embodiment of the present disclosure. As illustrated in FIG. 5, for example, the information processing system includes a plurality of initiators 10, an adjustment unit 30, a memory controller 40, and a DRAM 50.

### (DRAM 50)

The DRAM 50 is a DRAM conforming to the LPDDR5 or the LPDDR5X. As illustrated in FIG. 5, for example, two bank groups BG0 and GB1 are specified for the DRAM 50. For example, four banks Bank0, Bank1, Bank2, and Bank3 are specified for each of the bank groups BG0 and GB1. It is to be noted that respective numbers of the bank groups and the banks in the DRAM 50 are not limited to the above example.

The LPDDR5 or the LPDDR5X allows a dynamic drive frequency to be changed. In addition, there are a plurality of bank modes in the LPDDR5 or the LPDDR5X, the bank modes being usage of a bank configuration, and a specification that the bank modes vary depending on drive frequencies has been standardized.

In a case where BL16 and BL32 are used differently in units of commands, BL16 and BL32 being minimum burst units to the DRAM 50, a 16B (Bank) mode will be used for low-speed drive frequencies, and a BG (Bank Group) mode will be used for high-speed drive frequencies. In the BG mode, for data transfer with BL32, data is transferred in response to commands after a period of BL16 (1nCK). Such transfer penalty on the data line is a rule specific to the BG mode. However, because it is possible to include transfer data of another bank group in this transfer penalty period, it is possible to continuously issue transfer data on the data line.

### (Initiator 10)

The plurality of initiators 10 writes or reads data to or from the DRAM 50 via the adjustment unit 30 and the memory controller 40. Each of the initiators 10 is, for example, a central processing unit (CPU: Central Processing Unit) or a functional block, or the like.

Each of the initiators 10 issues a memory access request to write or read data to or from the DRAM 50, and outputs the memory access request to the adjustment unit 30. This memory access request includes, for example, a logical address in a virtual storage area given to each of the initiators 10, the BL length being a length of data to be accessed, identification information to identify the initiators 10, and a transfer direction. The transfer direction mentioned here is an indication of whether the memory access request is a write request to write data or a read request to read data. According to a data output instruction from the adjustment unit 30, each of the initiators 10 outputs, to the adjustment unit 30, write data to be written to the DRAM 50. Each of the initiators 10 communicates with the adjustment unit 30 using a protocol (AXI (Advanced eXtensible Interface) protocol, for example) defined by AMBA (Advanced Microcontroller Bus Architecture), for example.

### (Adjustment Unit 30)

As illustrated in FIG. 5, for example, the adjustment unit 30 includes an arbitration section 31, a RW switching detector 32, a buffer 33, a BL conversion judging section 34, and a BL converter 35.

The arbitration section 31 converts the logical address included in the memory access request outputted from each of the initiators 10 into a physical address corresponding to the DRAM 50. The physical address mentioned here is an address indicating a bank, a row, and a column that constitute the DRAM 50, and refers to a bank address, a row address, and a column address. By converting from the logical address into the physical address in this manner, the bank address, the row address, and the column address in the DRAM 50 are indicated in the converted memory access request.

The arbitration section 31 further performs arbitration (arbitration) on the basis of the physical addresses indicated in the plurality of memory access requests obtained from the plurality of initiators 10. In a case where the arbitration section 31 receives memory access requests simultaneously from the respective initiators 10, for example, the arbitration section 31 suppresses output of a memory access request having the same bank address as the bank address of the last memory access request outputted to the RW switching detector 32. That is, in a case where the arbitration section 31 receives the plurality of memory access requests simultaneously, the arbitration section 31 outputs, to the RW switching detector 32, a memory access request having a different bank address from the last memory access request outputted to the RW switching detector 32. In this manner, the arbitration section 31 adjusts order of outputting the plurality of memory access requests to the RW switching detector 32 by using an interleaving technique. In the BG mode, the arbitration section 31 further adjusts the order of outputting the plurality of memory access requests to the RW switching detector 32 by using the interleaving technique for each bank group. At this time, the arbitration section 31 adds a bank group identifier to the memory access request. When outputting a write request as a memory access request to the RW switching detector 32, the arbitration section 31 instructs the initiator 10 identified by the identification information indicated in the memory access request to output write data corresponding to the memory access request.

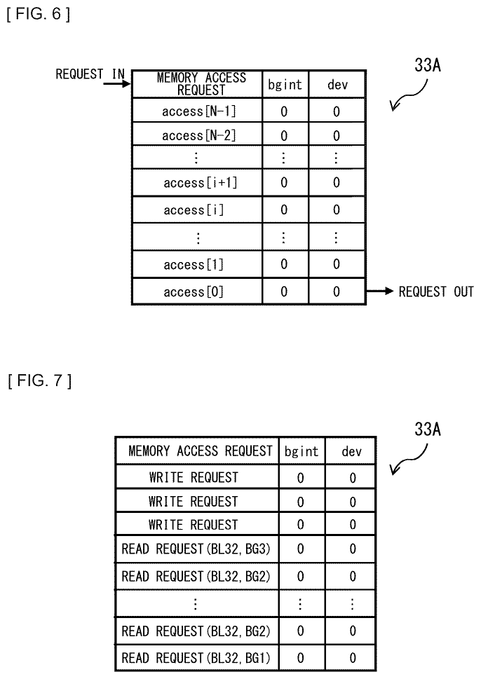

Every time the RW switching detector 32 receives a memory access request from the arbitration section 31, the RW switching detector 32 stores the received memory access request in the buffer 33. The buffer 33 includes, for example, a FIFO (First-In First-Out) memory 33A as illustrated in FIG. 6. In the FIFO memory 33A, a plurality of memory accesses is stored in order of storage. When a new memory access request is stored in the FIFO memory 33A, a memory access request with the oldest storage order is outputted from the FIFO memory 33A.

The FIFO memory 33A is associated with bank group information bgint and division necessity information dev for each memory access request stored. Every time a new memory access request is stored, the FIFO memory 33A outputs, to the BL converter 35, the memory access request with the oldest storage order in the FIFO memory 33A, together with the bank information bgint and the division necessity information dev.

The bank group information bgint is a flag for determining whether or not the memory access request is a memory access request of BG interleaving positioned immediately before the read/write switching, in the plurality of memory access requests stored in the FIFO memory 33A. For example, when the bank group information bgint is “1”, this means that the memory access request is the memory access request of the BG interleaving positioned immediately before the read/write switching. In addition, when the bank group information bgint is “0”, this means that the memory access request is not the memory access request of the BG interleaving positioned immediately before the read/write switching.

The division necessity information dev is a flag for determining whether or not to convert the BL length of a memory access request of BG interleaving included in the FIFO memory 33A from BL32 to BL16. For example, when the division necessity information dev is “1”, this means that it is necessary to convert the BL length of the memory access request from BL32 to BL16. In addition, for example, when the division necessity information dev is “0”, this means that it is not necessary to convert the BL length of the memory access request from BL32 to BL16.

The RW switching detector 32 detects switching from read BG interleaving (read request) to a write request or switching from write BG interleaving (write request) to a read request in the plurality of memory access requests stored in the buffer 33. Suppose that, for example, the plurality of memory access requests as illustrated in FIG. 7 is stored in the FIFO memory 33A. At this time, the RW switching detector 32 detects switching between the read request and the write request in the memory access request (read request) with the fifth oldest storage order and the memory access request (write request) with the sixth oldest storage order.

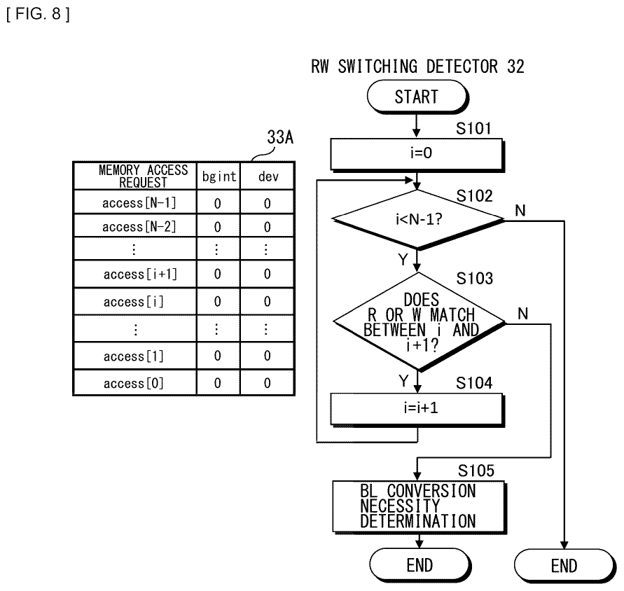

FIG. 8 illustrates an example of a procedure for detecting the above switching in the RW switching detector 32. The RW switching detector 32 sets a parameter i indicating the storage order to 0 (step S101). Next, the RW switching detector 32 judges whether or not the parameter i is smaller than the latest storage order N−1 (step S102). As a result, in a case where i<N−1 is satisfied (step S102; Y), the RW switching detector 32 compares an access request of the i-th storage order with an access request of the (i+1)-th storage order to judge whether or not both of the access requests are a read request or a write request (step S103). As a result, in a case where both are the read request or the write request (step S103; Y), the RW switching detector 32 adds 1 to the parameter i (step S104) and returns to step S102. In a case where both are not the read request or the write request (step S103; N), the RW switching detector 32 determines that switching from the read request to the write request or from the write request to the read request will be performed in the memory access request with the i-th storage order and the memory access request with the (i+1)-th storage order. Then, the RW switching detector 32 writes “1” to the bank group information bgint corresponding to the memory access request with the i-th storage order, and proceeds to BL conversion necessity determination (step S105). At this time, the RW switching detector 32 outputs the parameter i to the BL conversion judging section 34 as information on the above switching (RW switching information). It is to be noted that in a case where i<N−1 is not satisfied in step S102 (step S102; N), the RW switching detector 32 judges that there is no switching from the read request to the write request or from the write request to the read request, and ends this processing.

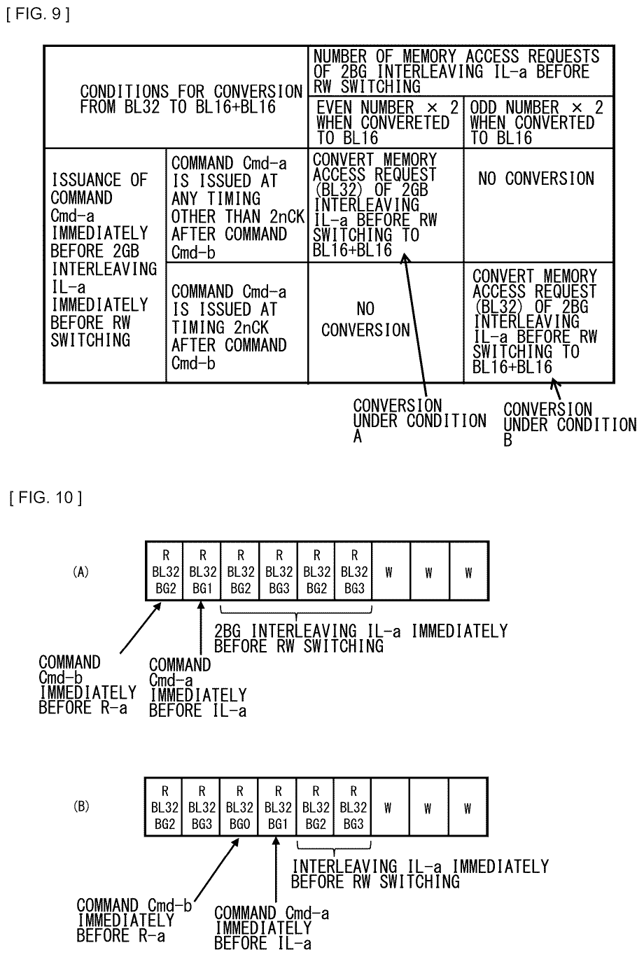

The BL conversion judging section 34 and the BL converter 35 convert the BL length of a memory access request included in 2BG interleaving IL-a (read BG group interleaving or write BG interleaving), on the basis of the number of memory access requests in the 2BG interleaving IL-a immediately before the above switching and timing information of a command Cmd-a (first command) corresponding to a memory access request R-a immediately before the 2BG interleaving IL-a. It is to be noted that the “2BG interleaving” refers to interleaving two bank groups. At this time, the BL conversion judging section 34 and the BL converter 35 determine whether or not to convert the BL length of the memory access request included in the 2BG interleaving IL-a on the basis of conditions described in FIG. 9.

FIG. 9 lists the conditions for determining whether or not to convert the BL length of the memory access request included in the 2BG interleaving IL-a. FIG. 9 lists the conditions for converting the BL length of the memory access request included in the 2BG interleaving IL-a from BL32 to BL16. In a case whether either of the following two conditions is satisfied, the BL conversion judging section 34 and the BL converter 35 convert the BL length of the memory access request included in the 2BG interleaving IL-a from BL32 to BL16. It is to be noted that the “command Cmd-b” included in the following condition A is a command corresponding to a memory access request R-b immediately before the memory access request R-a.

### Condition A

The number of memory access requests (number of memory access requests when converted to BL16 equivalent) in the 2BG interleaving IL-a is an even number×2, and the command Cmd-a is issued at any timing other than 2nCK after the command Cmd-b (second command) that is immediately before the command Cmd-a.

### Condition B

The number of memory access requests (number of memory access requests when converted to the BL16 equivalent) in the 2BG interleaving IL-a is an odd number×2, and the command Cmd-a is issued at a timing 2nCK after the command Cmd-b.

FIG. 10(A) and FIG. 10(B) are diagrams describing the 2BG interleaving IL-a, the command Cmd-a, and the command Cmd-b. FIG. 10(A) exemplifies a case in which the 2BG interleaving IL-a is configured so as to interleave two bank groups BG2 and BG3 with four read commands with BL32. FIG. 10(B) exemplifies a case in which the 2BG interleaving IL-a is configured so as to interleave the two bank groups BG2 and BG3 with two read commands with BL32.

In FIG. 10(A), the command Cmd-a is a read command with BL32 for a bank group BG1, and the command Cmd-b is a read command with BL32 for the bank group BG2. In contrast, in FIG. 10(B), the command Cmd-a is a read command with b132 for the bank group BG1, and the command Cmd-b is a read command with BL32 for the bank group BG0.

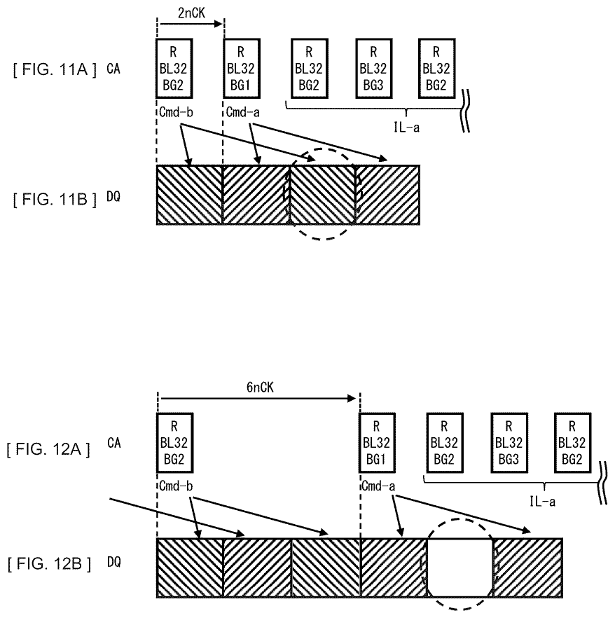

FIG. 11(A) illustrates an example of a timing of outputting each of commands to a command access line CA when a plurality of the commands is arranged in order illustrated in FIG. 10(A). FIG. 11(B) illustrates an example of a timing at which transfer data is each outputted to a data line DQ when each of the commands is outputted to the command access line CA at the timing of FIG. 11(A). In FIG. 11(A), the command Cmd-a is issued 2nCK after the command Cmd-b is issued.

FIG. 12(A) illustrates an example of the timing of outputting each of the commands to the command access line CA when the plurality of commands is arranged in the order illustrated in FIG. 10(A). FIG. 12(B) illustrates an example of a timing at which the transfer data is each outputted to the data line DQ when each of the commands is outputted to the command access line CA at the timing of FIG. 12(A). In FIG. 12(A), the command Cmd-a is issued 6nCK after the command Cmd-b is issued.

In a case where the command Cmd-a is issued 2nCK after the command Cmd-b is issued, it is seen that the transfer data corresponding to the command Cmd-a and the transfer data corresponding to the command Cmd-b fill the data line DQ without any gaps. In a case where the command Cmd-a is issued 6nCK after the command Cmd-b is issued, however, the data is transferred in response to the command Cmd-a after a gap of BL16 (1nCK). This does not allow the transfer data corresponding to the command Cmd-b to fill the gap, thus leaving the gap empty. The condition under which such a gap occurs correspond to the condition A.

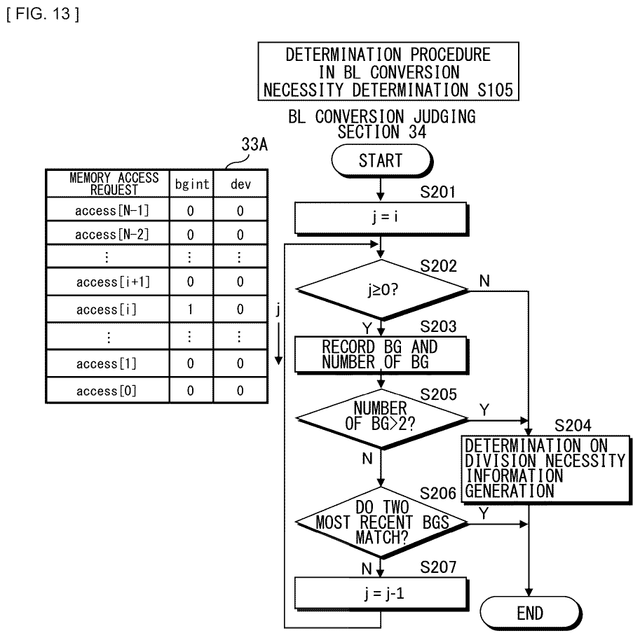

Next, a description will be given of an operation of the BL conversion judging section 34. FIG. 13 illustrates an example of a procedure for determining whether or not BL conversion is necessary, in the BL conversion judging section 34. FIG. 13 exemplifies the FIFO memory 33A in a state in which all flags have been initialized.

The BL conversion judging section 34 first copies the parameter i acquired from the RW switching detector 32 to a parameter j (step S201). Next, the BL conversion judging section 34 judges whether the parameter j is 0 or larger (step S202). In a case where the parameter j is 0 or larger (step S202; Y), the BL conversion judging section 34 accesses a memory access with j-th storage order stored in the FIFO memory 33A, and reads out the BG identifier included in the memory access request with the j-th storage order. Then, the BL conversion judging section 34 records, in an internal memory, BG identifiers and a number of the BG identifiers (the number of BGs) that are included in the memory access requests accessed from start of execution of step S201 until now (step S203). The BL conversion judging section 34 further records, in the internal memory, the number of memory access requests that have been accessed until now since the execution of step S201 started. In a case where the parameter j has a negative value (step S202; N), processing proceeds to determination on division necessity information generation (step S204).

After execution of step S203, the BL conversion judging section 34 judges whether or not the number of BGs recorded in the internal memory is 2 or larger (step S205). In a case where the number of BGs recorded in the internal memory is 2 or larger (step S205; Y), the BL conversion judging section 34 proceeds to the determination on division necessity information generation (step S204). In a case where the number of BGs recorded in the internal memory is 2 or smaller (step S205; N), the BL conversion judging section 34 judges whether or not identifiers of two most recently recorded BGs are equal to each other among the BG identifiers recorded in the internal memory (step S206).

In a case where the identifiers of the two most recently recorded BGs are equal to each other (step S206; Y), the BL conversion judging section 34 determines that the memory access request accessed last is not a valid request, and ends this processing. In a case where the identifiers of the two most recently recorded BGs are different from each other (step S206; N), the BL conversion judging section 34 determines that the memory access request accessed last is a valid request. Then, the BL conversion judging section writes “1” to the bank group information bgint corresponding to the memory access request with the j-th storage order stored in the FIFO memory 33A. The BL conversion judging section 34 further subtracts 1 from the parameter j (step S207), and returns to step S202.

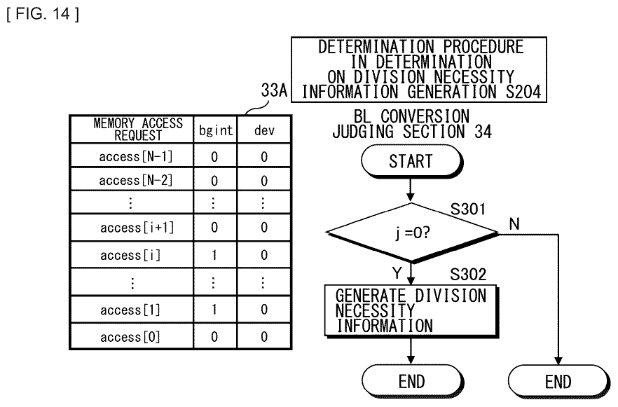

FIG. 14 illustrates an example of a procedure for determining on the division necessity information generation in the BL conversion judging section 34 (step S204). FIG. 14 exemplifies the FIFO memory 33A into which the flag after being processed as described in FIG. 13 has been written.

The BL conversion judging section 34 judges whether or not the parameter j is 0 (step S301). In a case where the parameter j is 0 (step S301; Y), the BL conversion judging section 34 proceeds to division necessity information generation (step S302). In a case where the parameter j is not 0 (step S301; N), the BL conversion judging section 34 ends the determination on division necessity information generation.

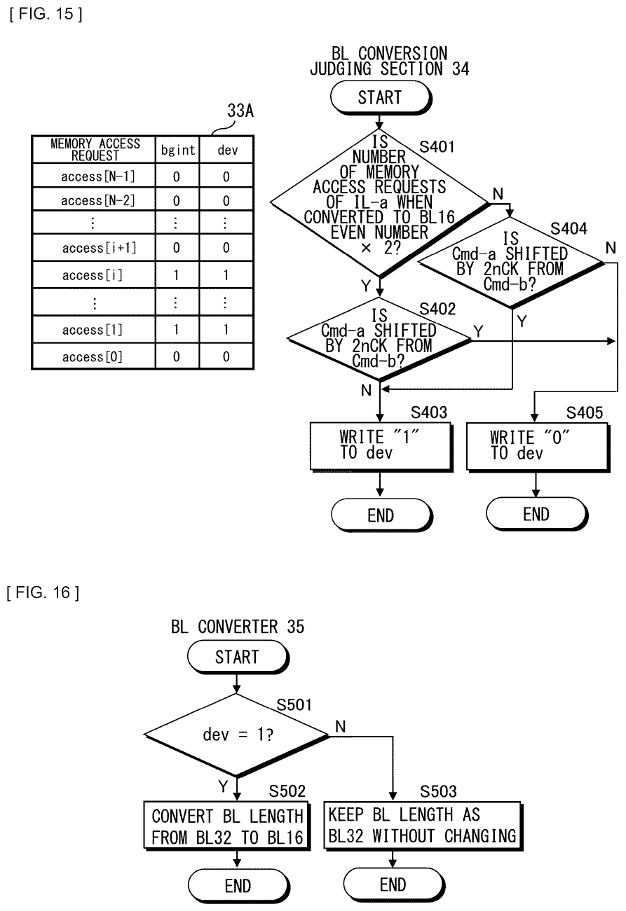

FIG. 15 illustrates an example of a procedure for generating the division necessity information in the BL conversion judging section 34. FIG. 15 exemplifies the FIFO memory 33A into which the flag after being processed as described in FIG. 15 has been written.

The BL conversion judging section 34 judges whether or not the number of the memory access requests recorded in the internal memory is an even number×2 (step S401). The “number of memory access requests recorded in the internal memory” mentioned above is the number of memory access requests of the BG interleaving IL-a (the number of memory access requests when converted to the BL16 equivalent). As a result, in a case where the number of the memory access requests recorded in the internal memory is an even number×2 (step S401; Y), the BL conversion judging section 34 judges on the basis of issuance timing information acquired from the command scheduler 41 whether or not the command Cmd-a is shifted by 2nCK from the command Cmd-b (step S402). Specifically, suppose that an issuance timing (time of issuance) of the command Cmd-b and the issuance timing (time of issuance) of the command Cmd-a have been obtained from the issuance timing information acquired from the command scheduler 41. At this time, it is possible for the BL conversion judging section 34 to judge from the time of issuance whether or not the command Cmd-a is shifted by 2nCK from the command Cmd-b.

As a result, in a case where the command Cmd-a is not shifted by 2nCK from the command Cmd-b (step S402; Y), the BL conversion judging section 34 writes “1” to the division necessity information dev corresponding to the memory access request of the BG interleaving IL-a, in the FIFO memory 33A (step S403).

In contrast, in a case where the number of memory access requests of the B G interleaving IL-a (number of memory access requests converted to the BL16 equivalent) is an odd number×2 (step S401; N), the BL conversion judging section 34 judges on the basis of the issuance timing information acquired from the command scheduler 41 whether or not the command Cmd-a is shifted by 2nCK from the command Cmd-b (step S404). Specifically, suppose that the issuance timing (time of issuance) of the command Cmd-b and the issuance timing (time of issuance) of the command Cmd-a have been obtained from the issuance timing information acquired from the command scheduler 41. At this time, it is possible for the BL conversion judging section 34 to judge from the time of issuance whether or not the command Cmd-a is shifted by 2nCK from the command Cmd-b.

As a result, in a case that the command Cmd-a is shifted by 2nCK from the command Cmd-b (step S404; Y), the BL conversion judging section 34 writes “1” to the division necessity information dev corresponding to the memory access request of the BG interleaving IL-a, in the FIFO memory 33A (step S403). In a case where in step S402, the memory access request R-a is not shifted by 2nCK from the memory access request R-b (step S404; N), or in a case where in step S402, the memory access request R-a is shifted by 2nCK from the memory access request R-b (step S402; Y), the BL conversion judging section 34 writes “0” to the division necessity information dev corresponding to the memory access request of the BG interleaving IL-a, in the FIFO memory 33A (step S405).

In the following, a description will be given of an operation of the BL converter 35. FIG. 16 illustrates an example of a BL conversion procedure in the BL converter 35. Every time anew memory access request is stored, the FIFO memory 33A outputs a memory access request with the oldest storage order in the FIFO memory 33A to the BL converter 35, together with the division necessity information dev. When the memory access request and the division necessity information dev are inputted from the FIFO memory 33A, the BL converter 35 judges whether or not the division necessity information dev is “1” (step S501). As a result, in a case where the division necessity information dev is “1” (step S501; Y), the BL converter 35 converts a BL length of the memory access request from BL32 to BL16 (step S502). Specifically, the BL converter 35 divides the memory access request with BL32 into two memory access requests with BL16. In a case where the division necessity information dev is “0” (step S501; N), the BL converter 35 keeps the BL length of the memory access request as BL32 without making a change (step S503).

Next, a description will be given of a specific method of converting the BL length of the memory access request of the BG interleaving IL-a.

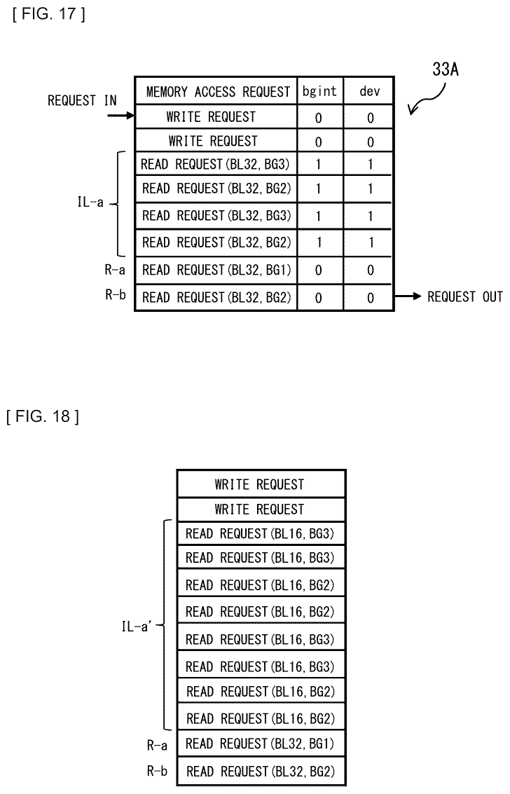

FIG. 17 illustrates an example of the FIFO memory 33A after flag writing processing is performed when the condition A is satisfied. In the following, a description will be given of output from the BL converter 35 when a plurality of memory access requests is sequentially inputted to the FIFO memory 33A as described in FIG. 17.

When anew memory access request is inputted to the FIFO memory 33A, the memory access request with the oldest storage order in the FIFO memory 33A (read request (BL32, BG2)=memory access request R-b) and the division necessity information dev are outputted to the BL converter 35. When the read request (BL32, BG2) and the division necessity information dev are inputted from the FIFO memory 33A, the BL converter 35 directly outputs the read request (BL32, BG2) to the memory controller 40 because dev=0.

When a memory access request is further inputted to the FIFO memory 33A, a memory request with the oldest storage order in the FIFO memory 33A (read request (BL32, BG1)=memory access request R-a) and the division necessity information dev are outputted to the BL converter 35. When the read request (BL32, BG1) and the division necessity information dev are inputted from the FIFO memory 33A, the BL converter 35 directly outputs the read request (BL32, BG1) to the memory controller 40 because dev=0.

When a memory access request is further inputted to the FIFO memory 33A, a memory request with the oldest storage order in the FIFO memory 33A (lead read request of the 2BG interleaving IL-a (BL32, BG2)) and the division necessity information dev are outputted to the BL converter 35. When the read request (BL32, BG2) and the division necessity information dev are inputted from the FIFO memory 33A, the BL converter 35 divides the read request (BL32, BG2) into two read requests (BL16, BG2), and outputs the read requests to the memory controller 40 because dev=1.

When a memory access request is further inputted to the FIFO memory 33A, a memory request with the oldest storage order in the FIFO memory 33A (second read request of the 2BG interleaving IL-a (BL32, BG3)) and the division necessity information dev are outputted to the BL converter 35. When the read request (BL32, BG3) and the division necessity information dev are inputted from the FIFO memory 33A, the BL converter 35 divides the read request (BL32, BG3) into two read requests (BL16, BG3), and outputs the read requests to the memory controller 40 because dev=1. The BL converter 35 thereafter outputs memory access requests to the memory controller 40 in the same manner as described above. As a result, a sequence of memory access requests as illustrated in FIG. 18, for example, is inputted to the memory controller 40. In FIG. 18, the plurality of memory access requests inputted to the memory controller 40 is arranged in order from a bottom.

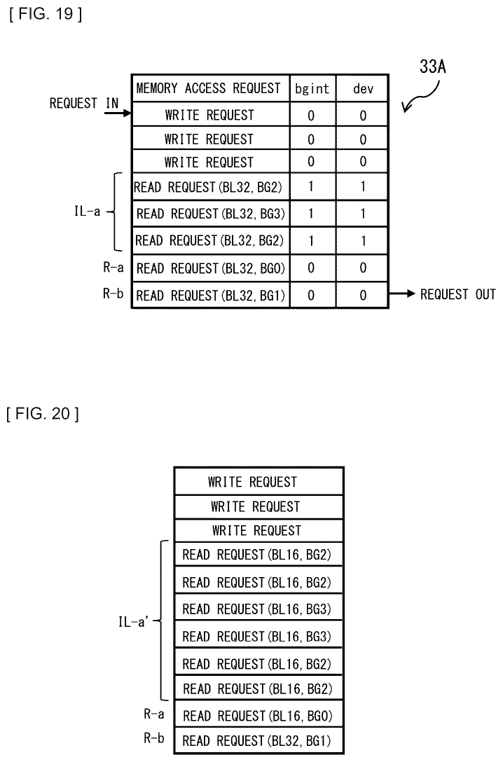

FIG. 19 illustrates an example of the FIFO memory 33A after the flag writing processing is performed when the condition B is satisfied. In the following, a description will be given of the output from the BL converter 35 when a plurality of commands is sequentially inputted to the FIFO memory 33A as described in FIG. 19.

When anew memory access request is inputted to the FIFO memory 33A, the memory access request with the oldest storage order in the FIFO memory 33A (read request (BL32, BG1)=memory access request R-b) and the division necessity information dev are outputted to the BL converter 35. When the read request (BL32, BG1) and the division necessity information dev are inputted from the FIFO memory 33A, the BL converter 35 directly outputs the read request (BL32, BG1) to the memory controller 40 because dev=0.

When a memory access request is further inputted to the FIFO memory 33A, a memory request with the oldest storage order in the FIFO memory 33A (lead read request (BL32, BG0)=memory access request R-a) and the division necessity information dev are outputted to the BL converter 35. When the read request (BL32, BG0) and the division necessity information dev are inputted from the FIFO memory 33A, the BL converter 35 directly outputs the read request (BL32, BG0) to the memory controller 40 because dev=0.

When a memory access request is further inputted to the FIFO memory 33A, a memory request with the oldest storage order in the FIFO memory 33A (lead read request of the 2BG interleaving IL-a (BL32, BG2)) and the division necessity information dev are outputted to the BL converter 35. When the read request (BL32, BG2) and the division necessity information dev are inputted from the FIFO memory 33A, the BL converter 35 divides the read request (BL32, BG2) into two read requests (BL16, BG2), and outputs the read requests to the memory controller 40 because dev=1.

When a memory access request is further inputted to the FIFO memory 33A, a memory request with the oldest storage order in the FIFO memory 33A (second read request of the 2BG interleaving IL-a (BL32, BG3)) and the division necessity information dev are outputted to the BL converter 35. When the read request (BL32, BG3) and the division necessity information dev are inputted from the FIFO memory 33A, the BL converter 35 divides the read request (BL32, BG3) into two read requests (BL16, BG3), and outputs the read requests to the memory controller 40 because dev=1. The BL converter 35 thereafter outputs memory access requests to the memory controller 40 in the same manner as described above. As a result, the sequence of memory access requests as illustrated in FIG. 20, for example, is inputted to the memory controller 40. In FIG. 20, the plurality of memory access requests inputted to the memory controller 40 is arranged in order from the bottom.

Next, a description will be given of the memory controller 40. As illustrated in FIG. 5, for example, the memory controller 40 includes the command scheduler 41 and an LPDDR-PHY (hereinafter simply referred to as a “physical layer”) 42.

The command scheduler 41 issues commands to the DRAM 50 on the basis of memory access requests inputted from the adjustment unit 30. At this time, the command scheduler 41 generates the issuance timing information for a command to be issued, and outputs the command to a physical layer 42 according to the generated issuance timing information. The command scheduler 41 outputs the generated issuance timing information to the BL conversion judging section 34.

The command scheduler 41 issues commands to a plurality of bank groups in the DRAM 50, for example, using a bank group interleaving technique for accessing the bank groups in parallel. The memory controller 40 outputs the data written in an internal buffer to the DRAM 50 in synchronization with the command issuance. The memory controller 40 reads out read data from the DRAM 50 in synchronization with the command issuance and stores the read data in the internal buffer.

The physical layer 42 outputs commands supplied synchronously with an operating clock of the memory controller 40 and the written data stored in the internal buffer, on the basis of a memory clock of the DRAM 50. The physical layer 42 also stores, in the internal buffer, the data read out synchronously with the memory clock in the DRAM 50, in synchronization with the operating clock of the memory controller 40.

The command scheduler 41 has a function to change order of accessing (out-of-order execution function) in order to improve the efficiency of memory access. In the following, a description will be given of the out-of-order execution function.

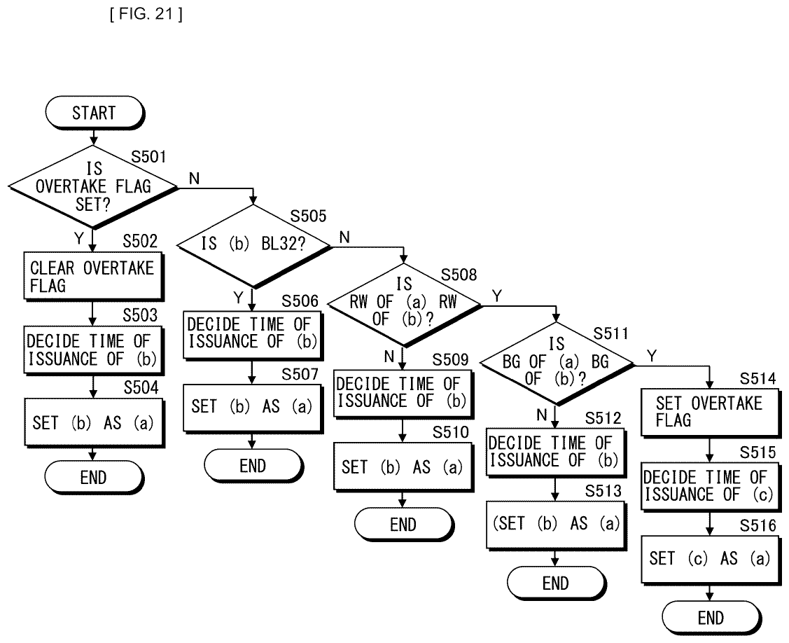

FIG. 21 illustrates an example of an out-of-order execution procedure. First, the command scheduler judges whether or not an overtake flag is set (step S501). As a result, in a case where the overtake flag is set (step S501; Y), the command scheduler 41 clears the overtake flag (step S502). At this time, the command scheduler 41 decides time to issue a command corresponding to (b), and sets the command corresponding to (b) as a command corresponding to (a) (steps S502 and S503).

In a case where the overtake flag is not set (step S501; N), the command scheduler 41 judges whether or not a BL length of the command corresponding to (b) is BL32 (step S505). As a result, in a case where the BL length of the command corresponding to (b) is BL32 (step S505; Y), the command scheduler 41 decides the time to issue the command corresponding to (b), and sets the command corresponding to (b) as the command corresponding to (a) (steps S506 and S507).

In a case where the BL length of the command corresponding to (b) is not BL32 (step S505; N), the command scheduler 41 judges whether or not the command corresponding to (a) and the command corresponding to (b) are both a read command or a write command (step S508). As a result, in a case where the command corresponding to (a) and the command corresponding to (b) are neither the read command nor the write command to each other (step S508; N), the command scheduler 41 decides the time to issue the command corresponding to (b), and sets the command corresponding to (b) as the command corresponding to (a) (steps S509 and S510).

In a case where the command corresponding to (a) and the command corresponding to (b) are both the read command or the write command (step S508; Y), the command scheduler 41 judges whether or not a BG of the command corresponding to (a) is equal to a BG of the command corresponding to (b) (step S511). As a result, in a case where the BG of the command corresponding to (a) differs from the BG of the command corresponding to (b) (step S511; N), the command scheduler 41 decides the time to issue the command corresponding to (b), and sets the command corresponding to (b) as the command corresponding to (a) (steps S512 and S513).

In a case where the BG of the command corresponding to (a) is equal to the BG of the command corresponding to (b) (step S511; Y), the command scheduler sets the overtake flag (step S514). Subsequently, the command scheduler 41 decides time to issue a command corresponding to (c), and sets the command corresponding to (c) as the command corresponding to (a) (steps S515 and S516).

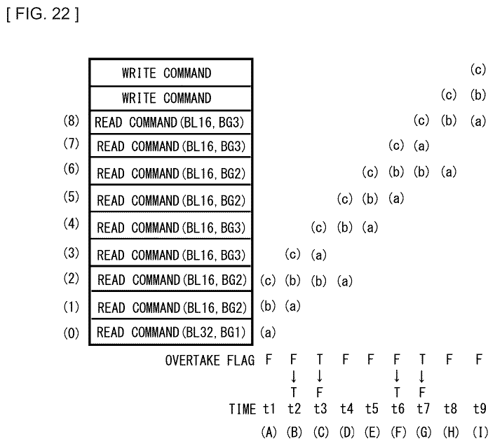

FIG. 22 illustrates an example of a sequence of commands generated by the command scheduler 41. Each time in FIG. 22 represents the time of issuance decided on the command corresponding to (b), and the command corresponding to (c) is the next oldest command after the command corresponding to (b).

As illustrated in FIG. 22(A), the command scheduler 41 assumes that the overtake flag is not set, the BL length of the command corresponding to (b) is BL16, the command corresponding to (a) and the command corresponding to (b) are both the read command, and the BG of the command corresponding to (a) differs from the BG of the command corresponding to (b) (steps S501; N, 505; N, S508; Y, and S511; N). At this time, the command scheduler 41 sets the time of issuance of the command corresponding to (b) to t1 (step S512). Furthermore, the command scheduler 41 outputs the command corresponding to (a) to the physical layer 42, and sets the command corresponding to (b) as the command corresponding to (a) (step S513).

Next, as illustrated in FIG. 22(B), the command scheduler 41 assumes that the overtake flag is not set, the BL length of the command corresponding to (b) is BL16, the command corresponding to (a) and the command corresponding to (b) are both the read command, and the BG of the command corresponding to (a) is equal to the BG of the command corresponding to (b) (steps S501; N, 505; N, S508; Y, and S511; Y). At this time, the command scheduler 41 sets the overtake flag, and sets the time of issuance of the command corresponding to (c) to t2 (steps S514 and S515). Furthermore, the command scheduler 41 outputs the command corresponding to (a) to the physical layer 42, and sets the command corresponding to (c) as the command corresponding to (a) (step S516).

Next, as illustrated in FIG. 22(C), in a case where the overtake flag is set (step S501; Y), the command scheduler 41 clears the overtake flag (step S502). At this time, the command scheduler 41 sets the time of issuance of the command corresponding to (b) to t3 (step S503). Furthermore, the command scheduler 41 outputs the command corresponding to (a) to the physical layer 42, and sets the command corresponding to (b) as the command corresponding to (a) (step S504).

Next, as illustrated in FIG. 22(D), the command scheduler assumes that the overtake flag is not set, the BL length of the command corresponding to (b) is BL16, the command corresponding to (a) and the command corresponding to (b) are both the read command, and the BG of the command corresponding to (a) differs from the BG of the command corresponding to (b) (steps S501; N, 505; N, S508; Y, and S511; N). At this time, the command scheduler 41 sets the time of issuance of the command corresponding to (b) to t4 (step S512). Furthermore, the command scheduler 41 outputs the command corresponding to (a) to the physical layer 42, and sets the command corresponding to (b) as the command corresponding to (a) (step S513).

Next, as illustrated in FIG. 22(E), the command scheduler 41 assumes that overtake flag is not set, the BL length of the command corresponding to (b) is BL16, the command corresponding to (a) and the command corresponding to (b) are both the read command, and the BG of the command corresponding to (a) differs from the BG of the command corresponding to (b) (steps S501; N, 505; N, S508; Y, and S511; N). At this time, the command scheduler 41 sets the time of issuance of the command corresponding to (b) to t5 (step S512). Furthermore, the command scheduler 41 outputs the command corresponding to (a) to the physical layer 42, and sets the command corresponding to (b) as the command corresponding to (a) (step S513).

Next, as illustrated in FIG. 22(F), the command scheduler 41 assumes that overtake flag is not set, the BL length of the command corresponding to (b) is BL16, the command corresponding to (a) and the command corresponding to (b) are both the read command, and the BG of the command corresponding to (a) is equal to the BG of the command corresponding to (b) (steps S501; N, 505; N, S508; Y, and S511; Y). At this time, the command scheduler 41 sets the overtake flag, and sets the time of issuance of the command corresponding to (c) to t6 (steps S514 and S515). Furthermore, the command scheduler 41 outputs the command corresponding to (a) to the physical layer 42, and sets the command corresponding to (c) as the command corresponding to (a) (step S516).

Next, as illustrated in FIG. 22(G), the command scheduler assumes that the overtake flag is set (step S501; Y). At this time, the command scheduler 41 clears the overtake flag, and sets the time of issuance of the command corresponding to (b) to t7 (steps S502 and S503). Furthermore, the command scheduler 41 outputs the command corresponding to (a) to the physical layer 42, and sets the command corresponding to (b) as the command corresponding to (a) (step S504).

Next, as illustrated in FIG. 22 (H), the command scheduler 41 assumes that the overtake flag is not set, the BL length of the command corresponding to (b) is BL16, the command corresponding to (a) and the command corresponding to (b) are both the read command, and the BG of the command corresponding to (a) differs from the BG of the command corresponding to (b) (steps S501; N, 505; N, S508; Y, and S511; N). At this time, the command scheduler 41 sets the time of issuance of the command corresponding to (b) is t8 (step S512). Furthermore, the command scheduler 41 outputs the command corresponding to (a) to the physical layer 42, and sets the command corresponding to (b) as the command corresponding to (a) (step S513).

Next, as illustrated in FIG. 22(I), the command scheduler 41 assumes that overtake flag is not set, and the BL length of the command corresponding to (b) is BL32 (steps S501; N and 505; Y). At this time, the command scheduler 41 sets the time of issuance of the command corresponding to (b) to t9 (step S506). Furthermore, the command scheduler 41 outputs the command corresponding to (a) to the physical layer 42, and sets the command corresponding to (b) as the command corresponding to (a) (step S507).

In this manner, the command scheduler 41 executes the out-of-order.

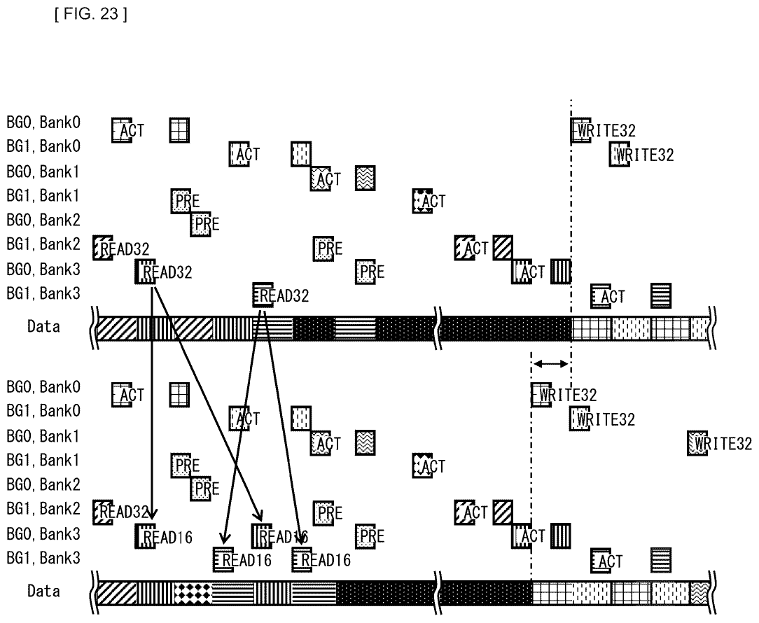

FIG. 23 illustrates an example of an operation of the command scheduler 41 when a sequence of commands that changes from a read command to a write command is inputted. The upper part of FIG. 23 illustrates an example of the operation of the command scheduler 41 when the BL length is BL32. The lower part of FIG. 23 illustrates an example of the operation of converting the BL lengths of the plurality of read commands (BL32, BG3) of specific BG interleaving from BL32 to BL16 in the operation of the command scheduler 41 illustrated in the upper part in FIG. 23. It is to be noted that the specific BG interleaving refers to BG interleaving constituted of a plurality of commands with “1” set to the division necessity information dev.

In the upper and lower parts of FIG. 23, the commands outputted to the address command line are illustrated, being divided for each bank group and bank address, and the data outputted to the data line is represented in different patterns for each bank group and bank address s. It is to be noted that the portions blacked out in the data line indicate that no data is outputted.

It is seen from FIG. 23 that conversion of the BL lengths of the plurality of read commands of the specific BG interleaving from BL32 to BL16 makes it possible to reduce penalty necessary for the read/write switching.

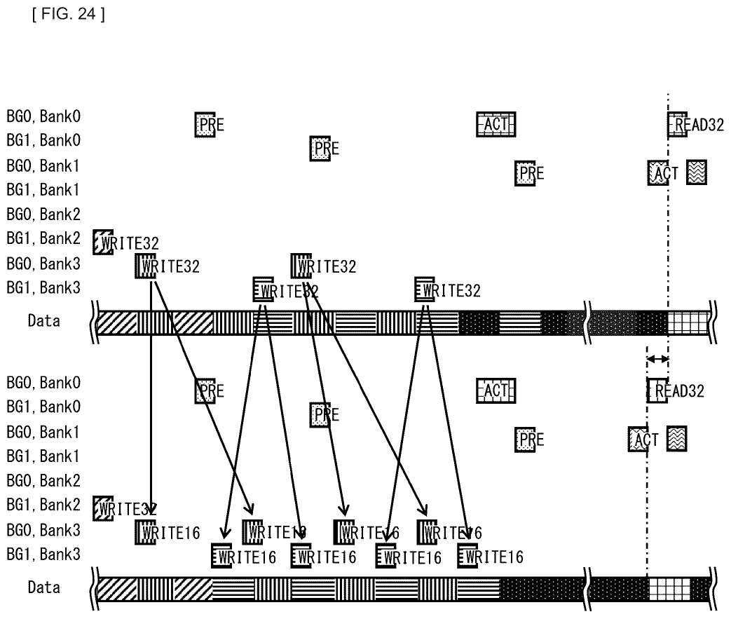

FIG. 24 illustrates an example of an operation of the command scheduler 41 when a sequence of commands that changes from the write command to the read command is inputted. The upper part of FIG. 24 illustrates an example of the operation of the command scheduler 41 when the BL length is BL32. The lower part of FIG. 24 illustrates an example of the operation of converting the BL lengths of the plurality of read commands (BL32, BG3) of the specific BG interleaving from BL32 to BL16 in the operation of the command scheduler 41 illustrated in the upper part in FIG. 24. It is to be noted that the specific BG interleaving refers to the BG interleaving constituted of the plurality of commands with “1” set to the division necessity information dev.

In the upper and lower parts of FIG. 24, the commands outputted to the address command line are illustrated, being divided by for each bank group and bank address, and the data outputted to the data line is represented in different patterns for each bank group and bank address. It is to be noted that the portions blacked out in the data line indicate that no data is outputted.

It is seen from FIG. 24 that the conversion of the BL lengths of the plurality of commands of the specific BG interleaving from BL32 to BL16 makes it possible to reduce the penalty necessary for the read/write switching.

### [Effects]

Next, a description will be given of effects of the information processing system according to the present embodiment.

In the present embodiment, the BL lengths of the memory access requests included in the read BG interleaving or the write BG interleaving are converted, on the basis of the number of the memory access requests in the read BG interleaving or the write BG interleaving and the timing information of the command corresponding to the memory access request immediately before the read bank group interleaving or the write bank group interleaving. This makes it possible to select the BL length in consideration of the efficiency of the access to the DRAM 50. As a result, it is possible to access the DRAM 50 more efficiently in the DRAM standards, such as the LPDDR5 or the LPDDR5X, having the BG and being compatible with the plurality of BL lengths.

In the present embodiment, in a case where either condition of the condition A and the condition B described above is satisfied, the BL length of the memory access request included in the read BG interleaving or the write BG interleaving is converted from BL32 to BL16. This makes it possible to select the BL length in consideration of the efficiency of the access to the DRAM 50. As a result, it is possible to access the DRAM 50 more efficiently in the DRAM standards, such as the LPDDR5 or the LPDDR5X, having the BG and being compatible with the plurality of BL lengths.

In the present embodiment, in a plurality of memory access requests, it is judged whether or not there is a memory access request corresponding to the read BG interleaving or the write BG interleaving, and a flag corresponding to a result of the judgment is written as the bank group information to the FIFO memory 33A of the buffer 33. This makes it possible to use the FIFO memory 33A to select the BL length in consideration of the efficiency of the access to the DRAM 50. As a result, it is possible to access the DRAM 50 more efficiently in the DRAM standards, such as the LPDDR5 or the LPDDR5X, having the BG and being compatible with the plurality of BL lengths.

In the present embodiment, it is judged on the basis of the issuance timing information acquired from the command scheduler 41 whether or not to convert the BL lengths of the plurality of flagged memory access requests, and the flag according to a result of the judgment is written as the division necessity information dev to the FIFO memory 33A of the buffer 33. This makes it possible to use the FIFO memory 33A to select the BL length in consideration of the efficiency of the access to the DRAM 50. As a result, it is possible to access the DRAM 50 more efficiently in the DRAM standards, such as the LPDDR5 or the LPDDR5X, having the BG and being compatible with the plurality of BL lengths.

### 3. MODIFICATION EXAMPLES

In the following, a description will be given of modification examples of the information processing system according to the aforementioned embodiment. In the following modification examples, a description will be given of configurations that are common to the aforementioned embodiments, using the same reference numerals.

### Modification Example A

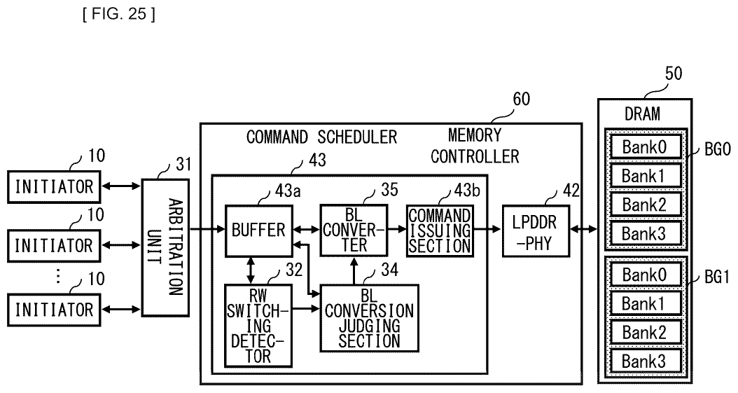

In the aforementioned embodiment and the modification examples of the aforementioned embodiment, as illustrated in FIG. 25, for example, a memory controller 60 may be provided instead of the adjustment unit 30 and the memory controller 40. The memory controller 60 includes a command scheduler 43 and the physical layer 42. The command scheduler 43 includes, for example, a buffer 43a, the RW switching detector 32, the BL converter 35, the BL conversion judging section 34, and a command issuing section 43b.

The buffer 43a includes the FIFO memory 33A, for example. Every time the buffer 43a receives a memory access request from the arbitration section 31, the buffer 43a stores the received memory access request in the FIFO memory 33A. The BL converter 35 outputs the memory access request outputted from the FIFO memory 33A to the command issuing section 43b. The BL converter 35 outputs the memory access request outputted from the FIFO memory 33A, to the command issuing section 43b.

The command issuing section 43b issues a command to the DRAM 50 on the basis of the memory access request inputted from the BL converter 35. The command issuing section 43b issues commands to the plurality of bank groups in the DRAM 50, for example, using the bank group interleaving technique for accessing the bank groups in parallel. The command issuing section 43b outputs the data written in the internal buffer to the DRAM 50 in synchronization with the command issuance. The command issuing section 43b reads out the read data from the DRAM 50 in synchronization with the command issuance and stores the read data in the internal buffer.

In this modification example, the function of the adjustment unit 30 is built into the memory controller 60. As configured in this manner, it is possible to use a command buffer within the memory controller 60 as the buffer 43a.

It is to be noted that in this modification example, the command issuing section 43b may output, to the BL conversion judging section 34, information related to a usage state of DQ pins managed within the memory controller 60. At this time, the BL conversion judging section 34 judges on the basis of the information related to the usage state of DQ pins whether or not a DQ pin becomes empty as illustrated in FIG. 12(B) (that is, whether or not the aforementioned condition A is satisfied). As a result, in a case where the BL conversion judging section 34 judges that the DQ pin becomes empty as illustrated in FIG. 12(B) (that is, the aforementioned condition A is satisfied), the BL length of the command included in the BG interleaving IL-a is converted from BL32 to BL16. Even in such a case, it is possible to select the BL length in consideration of the efficiency of the access to the DRAM 50. As a result, it is possible to access the DRAM 50 more efficiently in the DRAM standards, such as the LPDDR5 or the LPDDR5X, having the BG and being compatible with the plurality of BL lengths.

### Modification Example B

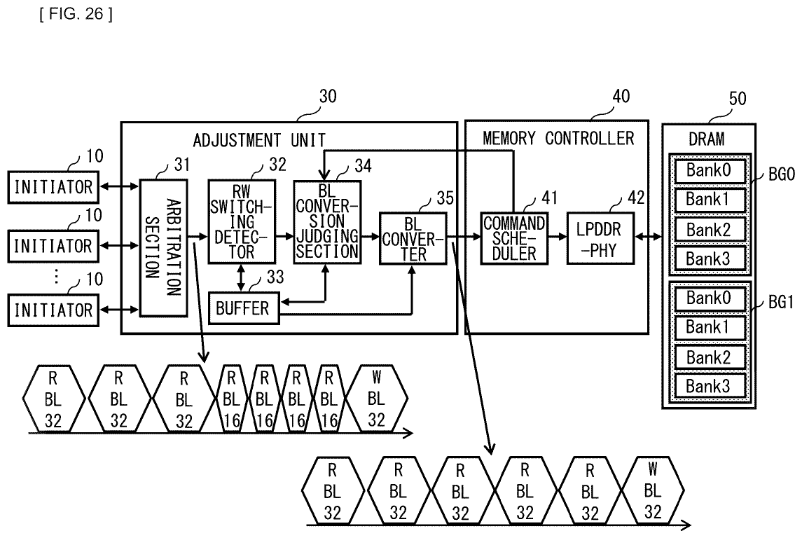

In the aforementioned embodiment and the modification example A, the BL length included in the memory access inputted from each of the initiators 10 is BL32 at all times. However, in the aforementioned embodiment and the modification example A, the BL length included in a portion of the memory access request inputted from each of the initiators 10 may be BL16 as illustrated in FIG. 26, for example.

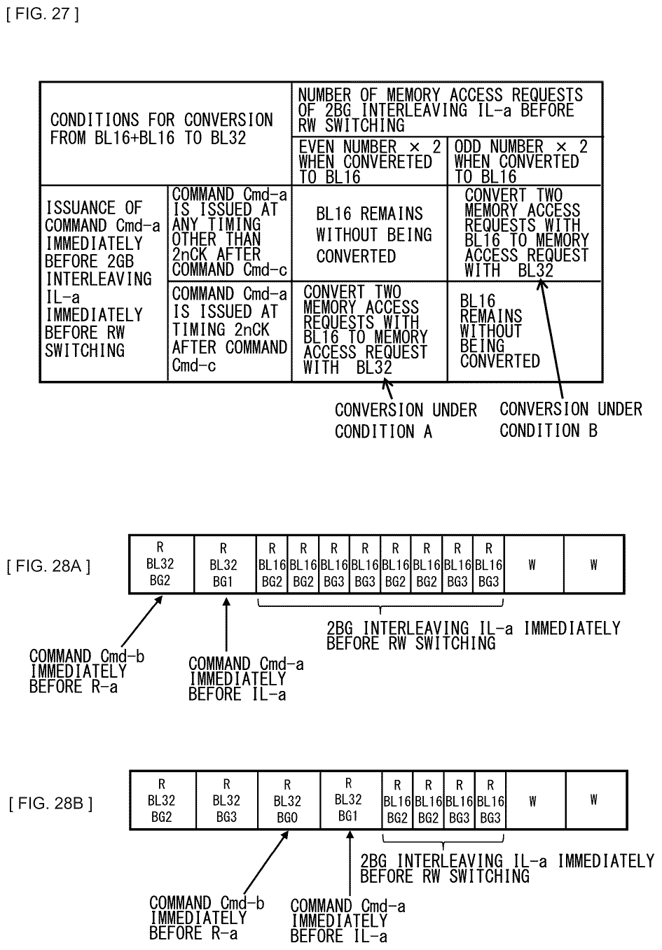

FIG. 27 illustrates the conditions for determining whether or not to convert the BL length included in the 2BG interleaving IL-a. FIG. 27 lists the conditions for converting the BL length of the command included in the 2BG interleaving IL-a from BL16 to BL32. In a case where neither of the following two conditions are satisfied, the BL conversion judging section 34 and the BL converter 35 convert the BL length of the command included in the 2BG interleaving IL-a from BL16 to BL32.

### Condition A

The number of memory access requests (number of memory access requests when converted to the BL16 equivalent) in the 2BG interleaving IL-a is an even number×2, and the command Cmd-a is issued at any timing other than 2nCK after the command Cmd-b (second command) that is immediately before the command Cmd-a.

### Condition B

The number of memory access requests (number of memory access requests when converted to the BL16 equivalent) in the 2BG interleaving IL-a is an odd number×2, and the command Cmd-a is issued at the timing 2nCK after the command Cmd-b.

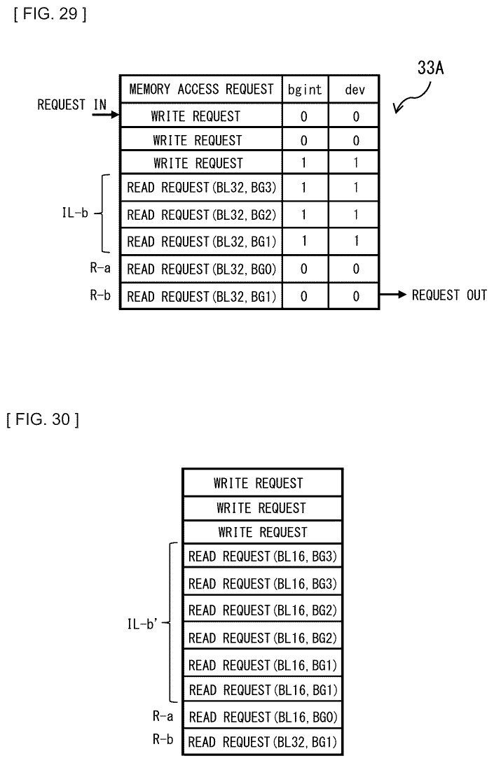

FIG. 28(A) and FIG. 28(B) are diagrams describing the 2BG interleaving IL-a, the command Cmd-a, and the command Cmd-b. FIG. 28(A) exemplifies a case in which the 2BG interleaving IL-a is configured so as to interleave the two bank groups BG2 and BG3 with eight read requests with BL16. FIG. 29(B) exemplifies a case in which the 2BG interleaving IL-a is configured so as to interleave the two bank groups BG2 and BG3 with four read commands with BL16.

In FIG. 28(A), the command Cmd-a immediately before the 2BG interleaving IL-a is the read command with BL32 for the bank group BG1, and the command Cmd-b immediately before the command Cmd-a is the read command with BL32 for the bank group BG2. In contrast, in FIG. 29(B), the command Cmd-a immediately before the 2BG interleaving IL-a is the read command with BL32 for the bank group BG1, and the command Cmd-b immediately before the command Cmd-a is the read command with BL32 for the bank group BG0.

In this modification example, in a case where neither of the above condition A nor the above condition B are satisfied, the BL length of the memory access request included in the read BG interleaving or the write BG interleaving is converted from BL16 to BL32. This makes it possible to select the BL length in consideration of the efficiency of the access to the DRAM 50. As a result, it is possible to access the DRAM 50 more efficiently in the DRAM standards, such as the LPDDR5 or the LPDDR5X, having the BG and being compatible with the plurality of BL lengths.

### Modification Example C

In the aforementioned embodiment and the modification examples A and B, the command scheduler 41 may interleave three bank groups. At this time, the BL conversion judging section 34 and the BL converter 35 convert the BL length of the memory access request included in 3BG interleaving IL-b (read BG group interleaving or write BG interleaving), on the basis of the number of memory access requests in the 3BG interleaving IL-b immediately before the read/write switching and the timing information of the command Cmd-a (first command) corresponding to the memory access request R-a immediately before the 3BG interleaving IL-b. It is to be noted that the “3BG interleaving” refers to interleaving three bank groups. At this time, the BL conversion judging section 34 and the BL converter 35 may determine whether or not to convert the BL length of the memory access request included in the 3BG interleaving IL-b on the basis of Condition A or Condition B listed below.

### Condition A

The number of memory access requests (number of memory access requests when converted to the BL16 equivalent) in the 3BG interleaving IL-a is an even number×2, and the command Cmd-a is issued at any timing other than 2nCK after the command Cmd-b (second command) that is immediately before the command Cmd-a.

### Condition B

The number of memory access requests (number of memory access requests when converted to the BL16 equivalent) in the 3BG interleaving IL-a is an odd number×2, and the command Cmd-a is issued at the timing 2nCK after the command Cmd-b.

At this time, the FIFO memory 33A described in FIG. 29, for example, is stored in the buffer 33. FIG. 29 illustrates an example of the FIFO memory 33A after the flag writing processing is performed when the Condition A is satisfied. In the following, a description will be given of the output from the BL converter 35 when the plurality of memory access requests is sequentially inputted to the FIFO memory 33A as described in FIG. 29.

When a new memory access request is inputted to the FIFO memory 33A, the memory access request with the oldest storage order in the FIFO memory 33A (read request (BL32, BG1)=memory access request R-b) and the division necessity information dev are outputted to the BL converter 35. When the read request (BL32, BG1) and the division necessity information dev are inputted from the FIFO memory 33A, the BL converter 35 directly outputs the read request (BL32, BG1) to the memory controller 40 because dev=0.

When a memory access request is further inputted to the FIFO memory 33A, a memory request with the oldest storage order in the FIFO memory 33A (lead read request (BL32, BG0)=memory access request R-a) and the division necessity information dev are outputted to the BL converter 35. When the read request (BL32, BG0) and the division necessity information dev are inputted from the FIFO memory 33A, the BL converter 35 directly outputs the read request (BL32, BG0) to the memory controller 40 because dev=0.

When a memory access request is further inputted to the FIFO memory 33A, a memory request with the oldest storage order in the FIFO memory 33A (lead read request of the 3BG interleaving IL-b (BL32, BG1)) and the division necessity information dev are outputted to the BL converter 35. When the read request (BL32, BG1) and the division necessity information dev are inputted from the FIFO memory 33A, the BL converter 35 divides the read request (BL32, BG1) into two read requests (BL16, BG1), and outputs the read requests to the memory controller 40 because dev=1.

When a memory access request is further inputted to the FIFO memory 33A, a memory request with the oldest storage order in the FIFO memory 33A (second read request of the 3BG interleaving IL-b (BL32, BG3)) and the division necessity information dev are outputted to the BL converter 35. When the read request (BL32, BG3) and the division necessity information dev are inputted from the FIFO memory 33A, the BL converter 35 divides the read request (BL32, BG3) into two read requests (BL16, BG3), and outputs the read requests to the memory controller 40 because dev=1. The BL converter 35 thereafter outputs commands to the memory controller 40 in the same manner as described above. As a result, the sequence of memory access requests as illustrated in FIG. 30, for example, are inputted to the memory controller 40. In FIG. 30, the plurality of memory access requests inputted to the memory controller 40 is arranged in order from the bottom.

In this modification example, the BL length of the memory access request included in the 3BG interleaving IL-b is converted, on the basis of the number of memory access requests of the 3BG interleaving IL-b immediately before the read/write switching and the timing information of the command Cmd-a corresponding to the memory access request immediately before the 3BG interleaving IL-b. Even in such a case, it is possible to select the BL length in consideration of the efficiency of the access to the DRAM 50. As a result, it is possible to access the DRAM 50 more efficiently in the DRAM standards, such as the LPDDR5 or the LPDDR5X, having the BG and being compatible with the plurality of BL lengths.

It is to be noted that in this modification example, the command scheduler 41 may interleave M bank groups. At this time, the BL conversion judging section 34 and the BL converter 35 may convert the BL length of the memory access request included in an MBG interleaving IL-b, on the basis of the number of memory access requests of the MBG interleaving IL-b (M≥4) immediately before the read/write switching and the timing information of the command Cmd-a (first command) corresponding to the memory access request R-a immediately before the MBG interleaving IL-b. It is to be noted that the “MBG interleaving” refers to interleaving M bank groups. At this time, the BL conversion judging section 34 and the BL converter 35 may determine whether or not to convert the BL length of the memory access request included in the 3BG interleaving IL-b on the basis of Condition A or Condition B listed below.

### Condition A

The number of memory access requests (number of memory access requests when converted to the BL16 equivalent) in the MBG interleaving IL-a is an even number×2, and the command Cmd-a is issued at any timing other than 2nCK after the command Cmd-b (second command) that is immediately before the command Cmd-a.

### Condition B

The number of memory access requests (number of memory access requests when converted to the BL16 equivalent) in the MBG interleaving IL-a is an odd number×2, and the command Cmd-a is issued at the timing 2nCK after the command Cmd-b.

Even in such a case, it is possible to select the BL length in consideration of the efficiency of the access to the DRAM 50. As a result, it is possible to access the DRAM 50 more efficiently in the DRAM standards, such as the LPDDR5 or the LPDDR5X, having the BG and being compatible with the plurality of BL lengths.

As described above, the present technology has been described with some embodiments and the modification examples of the embodiments. However, the present disclosure is not limited to the aforementioned embodiments, or the like, and various modifications are possible. It is to be noted that the effects described herein are merely examples. The effects of the present disclosure are not limited to the effects described herein. The present disclosure may have any effects other than the effects described herein.

In addition, the present disclosure may take, for example, the following configurations.

(1)

A memory control device including:
a detector that detects switching between read bank group interleaving and a write request or switching between write bank group interleaving and a read request in a plurality of memory access requests received for memory access; and
a converter that converts a BL length of a memory access request included in the read bank group interleaving or the write bank group interleaving, on the basis of a number of memory access requests in the read bank group interleaving or the write bank group interleaving and timing information of a first command corresponding to a memory access request immediately before the read bank group interleaving or the write bank group interleaving.
   (2)

The memory control device according to (1), in which the converter converts the BL length of the memory access request included in the read bank group interleaving or the write bank group interleaving from BL32 to BL16 in a case where one of two conditions below is satisfied:
a condition A that the number of memory access requests when converted to BL16 equivalent in the read bank interleaving or the write bank group interleaving is an even number×2, and the first command is issued at any timing other than a timing 2nCK after a second command that is immediately before the first command; and a condition B that the number of memory access requests when converted to the BL16 equivalent in the read bank interleaving or the write bank group interleaving is an odd number×2, and the first command is issued at the timing 2nCK after the second command.
   (3)

The memory control device according to (1), in which the converter converts the BL length of a command included in the read bank group interleaving or the write bank group interleaving from BL16 to BL32 in a case where neither of two conditions below are satisfied:
a condition A that the number of memory access requests when converted to BL16 equivalent in the read bank interleaving or the write bank group interleaving is an even number×2, and the first command is issued at any timing other than a timing 2nCK after the second command that is immediately before the first command; and
a condition B that the number of memory access requests when converted to the BL16 equivalent in the read bank interleaving or the write bank group interleaving is an odd number×2, and the first command is issued at the timing 2nCK after the second command.
   (4)

The memory control device according to (1) or (2) further including:
a storage unit that stores bank group information and division necessity information that are associated with the plurality of memory access requests, for each of the commands; and
a judging section that judges whether or not there is a memory access request corresponding to the read bank group interleaving or the write bank group interleaving in the plurality of memory access requests, and that writes a flag according to a result of the judging as the bank group information.
   (5)

The memory control device according to (4), in which the judging section judges on the basis of the timing information whether or not to convert BL lengths of a plurality of memory access requests to which the flag is set, and writes, in the storage unit, a flag according to a result of the judging as the division necessity information.

In the memory control device according to one embodiment of the present disclosure, the BL length of the memory access request included in the read bank group interleaving or the write bank group interleaving is converted, on the basis of the number of memory access requests in the read bank group interleaving or the write bank group interleaving and the timing information of the command corresponding to the memory access request immediately before the read bank group interleaving or the write bank group interleaving. This makes it possible to select the BL length in consideration of the efficiency of the access to the DRAM. As a result, it is possible to access the DRAM more efficiently in the DRAM standards, such as the LPDDR5 or the LPDDR5X, having the BG and being compatible with the plurality of BL lengths. It is to be noted that the effects of the present disclosure are not necessarily limited to the effects described here, and may be any effect described herein.

This application claims priority based on Japanese Patent Application No. 2022-059698 filed on Mar. 31, 2022 with Japan Patent Office, the entire contents of which are incorporated in this application by reference.

It should be understood by those skilled in the art that various modifications, combinations, sub-combinations and alterations may occur depending on design requirements and other factors insofar as they are within the scope of the appended claims or the equivalents thereof.

1. A memory control device comprising:
a detector that detects switching between read bank group interleaving and a write request or switching between write bank group interleaving and a read request in a plurality of memory access requests received for memory access; and
a converter that converts a BL length of a memory access request included in the read bank group interleaving or the write bank group interleaving, on the basis of a number of memory access requests in the read bank group interleaving or the write bank group interleaving and timing information of a first command corresponding to a memory access request immediately before the read bank group interleaving or the write bank group interleaving.

2. The memory control device according to claim 1, wherein the converter converts the BL length of the memory access request included in the read bank group interleaving or the write bank group interleaving from BL32 to BL16 in a case where one of two conditions below is satisfied:
a condition A that the number of memory access requests when converted to BL16 equivalent in the read bank interleaving or the write bank group interleaving is an even number×2, and the first command is issued at any timing other than a timing 2nCK after a second command that is immediately before the first command; and
a condition B that the number of memory access requests when converted to the BL16 equivalent in the read bank interleaving or the write bank group interleaving is an odd number×2, and the first command is issued at the timing 2nCK after the second command.

3. The memory control device according to claim 1, wherein the converter converts the BL length of a command included in the read bank group interleaving or the write bank group interleaving from BL16 to BL32 in a case where neither of two conditions below are satisfied:
a condition A that the number of memory access requests when converted to BL16 equivalent in the read bank interleaving or the write bank group interleaving is an even number×2, and the first command is issued at any timing other than a timing 2nCK after the second command that is immediately before the first command; and
a condition B that the number of memory access requests when converted to the BL16 equivalent in the read bank interleaving or the write bank group interleaving is an odd number×2, and the first command is issued at the timing 2nCK after the second command.

4. The memory control device according to claim 1 further comprising:
a storage unit that stores bank group information and division necessity information that are associated with the plurality of memory access requests, for each of the commands; and
a judging section that judges whether or not there is a memory access request corresponding to the read bank group interleaving or the write bank group interleaving in the plurality of memory access requests, and that writes a flag according to a result of the judging as the bank group information.

5. The memory control device according to claim 4, wherein the judging section judges on the basis of the timing information whether or not to convert BL lengths of a plurality of memory access requests to which the flag is set, and writes, in the storage unit, a flag according to a result of the judging as the division necessity information.
